(19) United States
(12) Patent Application Publication
(10) Pub. No.: US 2017/0069387 A1
(43) Pub. Date: Mar. 9, 2017

(54) NONVOLATILE SEMICONDUCTOR MEMORY AND METHOD OF CONTROLLING THE NONVOLATILE SEMICONDUCTOR MEMORY

(71) Applicant: Kabushiki Kaisha Toshiba, Minato-ku (JP)

(72) Inventor: Hideto TAKEKIDA, Nagoya (JP)

(73) Assignee: Kabushiki Kaisha Toshiba, Minato-ku (JP)

(21) Appl. No.: 15/002,514

(22) Filed: Jan. 21, 2016

Related U.S. Application Data
(60) Provisional application No. 62/216,006, filed on Sep. 9, 2015.

(51) Int. Cl. G11C 16/14; G11C 16/04

(52) U.S. Cl. CPC G11C 16/14; G11C 16/0483

(57) ABSTRACT

A nonvolatile semiconductor memory includes a memory cell array, the memory cell array including a memory string and a matrix of a plurality of memory cell units, the memory string containing a plurality of memory cells that are provided on the substrate, store data according to a threshold voltage, allow electrical writing and erasure of data, and are connected in series, the memory cell unit containing a first selecting gate transistor that connects a first end of the memory string to a bit line and a second selecting gate transistor that connects a second end of the memory string to a source line. After data is written in selected one of the memory cells, the voltage of the substrate is controlled for a specified period to be higher than a voltage of a word line connected to the selected memory cell.

### CROSS-REFERENCE TO RELATED APPLICATION

This application is based upon and claims the benefit of U.S. provisional Application No. 62/216,006, filed on Sep. 9, 2015, the entire contents of which are incorporated herein by reference.

### FIELD

Embodiments described herein relate generally to nonvolatile semiconductor memory and a method of controlling the nonvolatile semiconductor memory.

### BACKGROUND

In recent years, data retention of memory cells has deteriorated in NAND flash memories according to size reduction of the memory cells.

If the number of times writing operations and erasure operations are performed particularly increases and the gate insulating films of the memory cells are deteriorated, data retention tends to decrease. Thus, after the completion of a writing operation and a writing verifying operation, the lower limit of a threshold voltage may fall below a writing verifying voltage. The reduction in threshold voltage may deteriorate the data retention of memory cells.

### BRIEF DESCRIPTION OF THE DRAWINGS

FIG. 1 is a block diagram showing a configuration example of an NAND flash memory 100 according to a first embodiment that is an aspect of the present invention;

FIG. 2 is a cross-sectional view showing one of the memory cells M in the memory cell array 1 shown in FIG. 1;

FIG. 3 is a flowchart showing an example of a writing method of the NAND flash memory 100 shown in FIG. 1;

FIG. 4 is a timing chart showing an example of operating wavelengths in a writing operation and an operation for suppressing electron trap of the NAND flash memory 100 shown in FIG. 1;

FIG. 5 is a timing chart showing another example of operating wavelengths in a writing operation and an operation for suppressing electron trap in the NAND flash memory 100 of FIG. 1; and

FIG. 6 is a timing chart showing still another example of operating wavelengths in a writing operation and an operation for suppressing electron trap in the NAND flash memory 100 of FIG. 1.

### DETAILED DESCRIPTION

A nonvolatile semiconductor memory according to an embodiment includes a memory cell array, the memory cell array including a memory string and a matrix of a plurality of memory cell units, the memory string containing a plurality of memory cells that are provided on the substrate, store data according to a threshold voltage, allow electrical writing and erasure of data, and are connected in series, the memory cell unit containing a first selecting gate transistor that connects a first end of the memory string to a bit line and a second selecting gate transistor that connects a second end of the memory string to a source line. The nonvolatile semiconductor memory a driver that controls a voltage of a substrate. After data is written in selected one of the memory cells, the voltage of the substrate is controlled for a specified period to be higher than a voltage of a word line connected to the selected memory cell.

### DETAILED DESCRIPTION OF THE INVENTION

According to embodiments, a nonvolatile semiconductor memory and a method of controlling the nonvolatile semiconductor memory are proposed in which a positive voltage is applied to a substrate (well) after the end of a program so as to draw electrons trapped in a gate oxide film or the like. This can suppress a reduction in threshold voltage.

The embodiments will be described below with reference to the accompanying drawings.

### First Embodiment

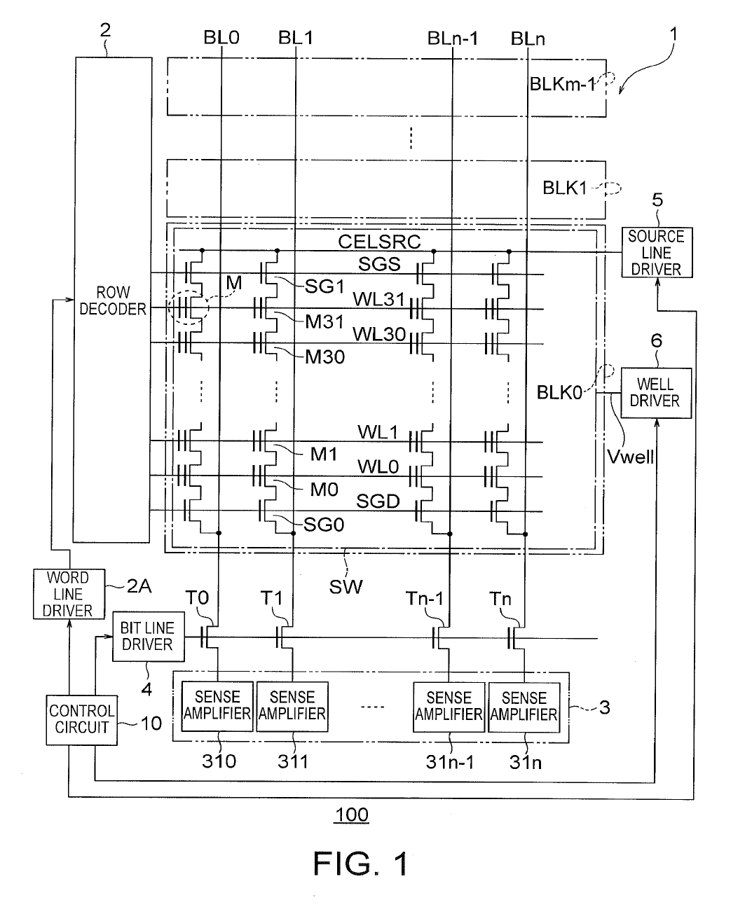

FIG. 1 is a block diagram showing a configuration example of an NAND flash memory 100 according to a first embodiment that is an aspect of the present invention.

As shown in FIG. 1, the NAND flash memory 100 includes a memory cell array 1, a row decoder 2, a word line driver 2A, a sense amplifier circuit 3, a bit line driver 4, a source line driver 5, a well driver 6, clamp transistors T0 to Tn (n: a positive integer), and a control circuit 10.

The memory cell array 1 includes a plurality of bit lines BL0 to BLn, a plurality of word lines WL0 to WL31, and a source line CELSRC. The memory cell array 1 includes, for example, a plurality of NAND cell blocks BLK0 to BLKm−1 (m: a positive integer), each having a matrix of memory cells M (M0 to M31) including EEPROM cells capable of electrically rewriting data.

Moreover, the adjacent memory cells (memory cell transistors) M (M0 to M31) are connected in series with a shared source or drain in a column direction. Selecting gate transistors SG0 and SG1 are disposed on both ends of the column so as to constitute an NAND cell unit.

A matrix of such NAND cell units constitutes the memory cell array 1. Moreover, the NAND cell blocks BLK0 to BLKm−1 each include NAND cell units arranged in a row direction. The gates of the selecting gate transistors SG0 in the same row are connected to the same select gate line while the control gates of memory cells M in the same row are connected to the same control gate line.

In the example of FIG. 1, the memory cell array 1 includes memory strings MS, each having the electrically rewritable 32 memory cells M0 to M31 connected in series. The number of memory cells M in the memory string MS is not limited to 32. For example, the number of memory cells M may be 64 or 128.

The drain-side selecting gate transistor SG0 and the source-side selecting gate transistor SG1, which are brought into conduction when the memory string MS is selected, are connected to both ends of the memory string MS. In the example of FIG. 1, the 32 memory cells M0 to M31 and the two selecting gate transistors SG0 and SG1 constitute the NAND cell unit.

Specifically, each of the NAND cell units is connected to the bit line BL (BL0 to BLn) on one end of the drain-side selecting gate transistor SG0 and is connected to the source line CELSRC on one end of the source-side selecting gate transistor SG1.

The control gates of the memory cells M0 to M31 in the NAND cell unit are connected to respectively different word lines WL0 to WL31. The gates of the selecting gate transistors SG0 and SG1 are connected to select gate lines SGD and SGS parallel to the word lines WL0 to WL31.

The word lines WL (WL0 to WL31) and the select gate lines SGD and SGS are selectively driven by the outputs of the word line driver 2A and the row decoder 2.

The bit lines BL0 to BLn are respectively connected to sense amplifiers 310 to 31n in the sense amplifier circuit 3. The bit lines BL0 to BLn are charged to a predetermined voltage by a precharge circuit (not shown), which is included in each of the sense amplifiers 310 to 31n, during a reading operation. The bit lines BL and the sense amplifiers 310 to 31n are connected via the clamp transistors T0 to Tn, respectively. The gate voltages of the clamp transistors T0 to Tn are controlled by the bit line driver 4.

In this configuration, the bit lines BL0 to BLn are connected to the sense amplifiers 310 to 31n on a one-to-one basis. In this case, the memory cells M selected by one of the word lines serve as pages for simultaneous writing/reading. However, one of the sense amplifiers may be shared by the adjacent even and odd numbered bit lines. In this case, a half number of the memory cells selected by one of the word lines serves as units for simultaneous writing/reading.

Moreover, a set of the NAND cell units sharing the word lines constitutes a block serving as a unit for data erasure. In the example of FIG. 1, the blocks BLK0, BLK1, . . . , and BLKm−1 are disposed along the bit lines BL (BL0 to BLn).

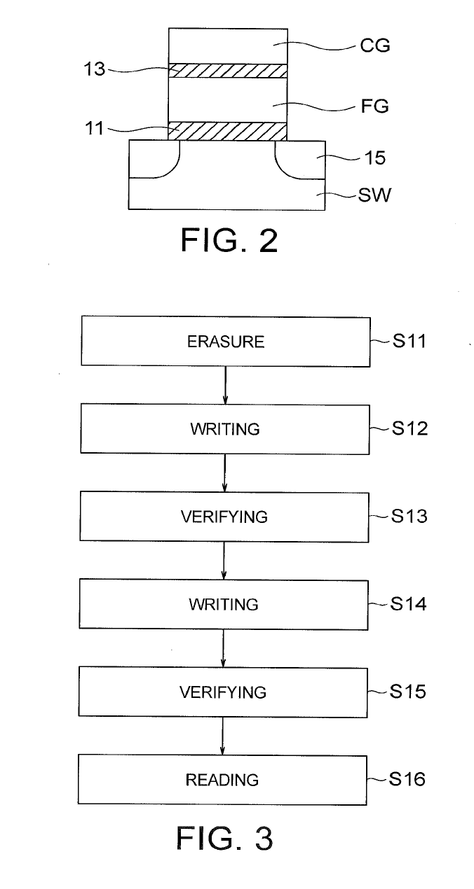

FIG. 2 is a cross-sectional view showing one of the memory cells M in the memory cell array 1 shown in FIG. 1.

As shown in FIG. 2, the memory cell M includes a floating gate FG, a control gate CG (WL), and a diffusion layer 15. The control gate CG is electrically connected to the word line WL shared by the multiple memory cells M.

A well (p well) SW formed on a semiconductor substrate (not shown) has the diffusion layer 15 that serves as a source/drain diffusion layer (n+ diffusion layer) in the memory cell M. Furthermore, a gate insulating film (tunnel insulating film) 11 is provided on the substrate (well SW). The floating gate (charge storage layer) FG is provided on the gate insulating film (tunnel insulating film) 11. Moreover, a gate insulating film (intermediate insulating film) 13 is provided on the floating gate FG. The control gate CG is provided on the gate insulating film (intermediate insulating film) 13.

The memory cell M can store data according to a threshold voltage and rewrite the stored data by controlling the threshold voltage. The threshold voltage is determined by the amount of charge stored in the floating gate FG. The amount of charge in the floating gate FG can be changed by a tunnel current passing through the gate insulating film 11.

Specifically, if the control gate CG is set at a sufficiently high voltage relative to the well SW and the diffusion layer (source diffusion layer/drain diffusion layer) 15, electrons are injected into the floating gate FG through the gate insulating film 11. This increases the threshold voltage of the memory cell M (corresponds to a writing state if binary data is stored).

Meanwhile, if the well SW and the diffusion layer (source diffusion layer/drain diffusion layer) 15 are set at a sufficiently high voltage relative to the control gate CG, electrons are emitted from the floating gate FG through the gate insulating film 11. This reduces the threshold voltage of the memory cell M (corresponds to an erasing state if binary data is stored).

In this way, the memory cell M can rewrite the stored data by controlling the amount of charge stored in the floating gate FG.

In the example of FIG. 2, the memory cell M is a floating-gate memory cell. The floating-gate memory cell M may be replaced with, for example, a MONOS memory cell having a charge storage layer including a silicon nitride film.

As shown in FIG. 1, the memory cell array 1 is connected to the sense amplifier circuit 3 that controls the voltages of the bit lines and the row decoder 2 that controls the voltages of the word lines. During a data erasure operation, one of the blocks is selected by the row decoder 2 while the other blocks are unselected. The row decoder 2 applies a voltage for reading, writing, or erasure to the word lines of the memory cell array 1 according to the output of the word line driver 2A controlled by the control circuit 10.

The sense amplifier circuit 3 includes the sense amplifiers 310 to 31n.

The sense amplifiers 310 to 31n amplify the voltages of the bit lines BL0 to BLn in the memory cell array 1. The sense amplifiers 310 to 31n each include a data latch circuit that latches data to be written.

The sense amplifier circuit 3 reads data from the memory cell M in the memory cell array 1 through the bit lines BL, detects a state of the memory cell M through the bit line BL, and applies a writing control voltage to the memory cell M through the bit line BL so as to write data in the memory cell M.

The sense amplifier circuit 3 is connected to a column decoder (not shown) and a data input/output buffer (not shown). The data latch circuits in the sense amplifier circuit 3 are selected by the column decoder. Data from the memory cell transistor is read from the selected data latch circuit and then is outputted to the outside through the data latch circuit and a data input/output buffer (not shown).

Moreover, write data inputted from the outside is stored in the data latch circuit selected by the column decoder, through the data input/output buffer (not shown).

As described above, the source line driver 5 is connected to the memory cell array 1. The source line driver 5 controls the voltage of the source line CELSRC.

As has been discussed, the well driver 6 is connected to the memory cell array 1. The well driver 6 controls the voltage of the semiconductor substrate (well SW) having the memory cells M formed.

For example, in a negative sense scheme, the source line driver 5 and the well driver 6 increase a voltage VCELSRC of the source line CELSRC and a voltage Vwell of the well SW to a voltage VCELSRC (>0) and a voltage Vwell (Vwell>0, VCELSRC≧Vwell). In order to prevent application of a substrate bias, the voltage VWell is set equal to the voltage VCELSRC or smaller than the voltage VCELSRC.

The control circuit 10 performs a control operation in response to a control signal (e.g., a command latch enable signal, an address latch enable signal, and a ready/busy signal) and a command that are inputted from the outside. Specifically, the control circuit 10 generates a desired voltage in response to the control signal and the command during a data program, verification, reading, or erasure, and then the control circuit 10 outputs the voltage to the parts of the memory cell array 1.

In other words, the control circuit 10 controls the word line driver 2A, the bit line driver 4, the source line driver 5, and the well driver 6 and controls voltages applied to the word lines WL0 to WLn, the bit lines BL0 to BLn, the source line CELSRC, and the well SW.

After the completion of a writing operation, if a writing verifying operation is performed to confirm the completion of the writing operation, particularly, the control circuit 10 temporarily increases the voltage of the bit line or the source line, before the writing verifying operation, to a light erasure voltage that is higher than a voltage applied to the bit line or the source line during the writing verifying operation.

An operation example of the NAND flash memory 100 configured thus will be described below.

FIG. 3 is a flowchart showing an example of a writing method of the NAND flash memory 100 shown in FIG. 1. Multivalued data (e.g., quaternary data) is determined by, for example, a negative threshold voltage distribution (erasure distribution) at the lowest voltage level and a different threshold voltage distribution at a higher voltage level than the negative threshold voltage distribution.

To write the multivalued data, all the memory cells M of the selected block are set at the lowest negative threshold voltage distribution (data erasure: step S11).

In the data erasure, a positive erasing voltage Vera is applied from the well driver 6 to the well SW where the memory cell array 1 is formed, all the word lines WL0 to WLn of the selected block are set at 0 V, and then the electrons of the floating gates of all the memory cells are emitted.

Subsequently, the control circuit 10 performs lower-page writing (Lower Page Program) in which the cells of the threshold voltage distribution at the lowest level are partially written to an intermediate distribution (Step S12).

After that, a verify voltage is set at the lower limit voltage of the intermediate distribution (the lower limit voltage is applied across the gate and source of the selected memory cell M) and then a verifying operation is performed to confirm the completion of writing to the intermediate distribution (Step S13).

Subsequently, the control circuit 10 performs upper page writing in which the threshold voltage is increased from the threshold voltage distribution at the lowest level to a higher-level threshold voltage distribution and from the intermediate distribution to a higher-level threshold voltage distribution (Step S14).

After that, the control circuit 10 performs a verifying operation using the lower limit voltage of the threshold voltage distribution as a verify voltage (Step S15).

After the completion of writing to all the threshold voltage distributions, the control circuit 10 optionally performs a reading operation (Step S16).

In the reading operation, the control circuit 10 sets a reading voltage applied across the gate and source of the selected memory cell M at a reading voltage between the upper and lower limit voltages of the threshold voltage distributions; meanwhile, the control circuit 10 applies a reading pass voltage VREAD, which is sufficiently higher than the upper limit value of the threshold voltage distribution, across the gate and source of the unselected memory cell M that are not selected.

The reading pass voltage VREAD can bring the memory cells M into conduction regardless of data retained in the memory cells M.

The above data writing is an operation that applies a writing voltage VPGM to the selected word line WL, a writing pass voltage VPASS to the unselected word line WL, and a ground voltage (in the case of“0” writing for increasing the threshold voltage) or a power supply voltage (in the case of writing inhibition not increasing the threshold voltage) to the bit lines, selectively injecting electrons to the floating gates of the memory cells M.

In the case of “0” writing, a ground voltage Vss applied to the bit lines BL is transferred to the channel of the NAND cell unit. At the application of the writing voltage VPGM, electrons are injected from the channel of the NAND cell unit to the floating gate by a tunnel current.

Meanwhile, in the case of “1” writing, the channel of the NAND cell unit is charged to a power supply voltage Vdd−a threshold voltage Vt (“Vt” denotes the threshold voltage of the drain-side selecting gate transistor SG0) and is placed in a floating state. Thus, at the application of the writing voltage VPGM, the channel of the NAND cell unit is boosted by capacitive coupling, preventing electron injection.

Data is typically written using a step-up writing scheme that gradually increases a writing voltage in every writing cycle (a writing operation and a verifying operation).

In lower-page writing (writing in an intermediate distribution LM), a writing state is confirmed (verifying operation) is performed to set the lower limit threshold voltage of the intermediate distribution LM at a predetermined voltage (verifying voltage VLM) or higher. Specifically, in a writing verifying operation that applies the verifying voltage VLM across the control gate (selected word line) and source of the selected memory cell, electrical connection of the selected memory cell M indicates unsuccessful writing (fail), whereas electrical disconnection of the selected memory cell M indicates successful writing (pass). In upper-page writing, verifying operation is similarly performed for a data status according to a verifying voltage.

In an NAND flash memory, as memory cells are multivalued and reduced in size, the voltage value of a threshold voltage distribution E (a negative value having a large absolute value) decreases after data erasure. In this case, if data is written from the threshold voltage distribution in the erased state with such a low voltage value, the threshold voltage distribution may have a negative voltage instead of a positive voltage after the writing.

As described above, in an NAND flash memory, as memory cells are reduced in size, the data retention of memory cells deteriorate with the number of times writing operations and erasure operations are performed.

In a writing operation (Program), for example, a high voltage of at least 20 V is applied to the selected word line. Thus, charge is trapped in the floating gate of the memory cell M according to data and the threshold voltage distribution for data to be written can be obtained in the selected memory cell.

In a verifying operation (Verify) immediately after a writing operation, a writing verifying voltage is applied to the selected word line. For example, if the lower limit value of the threshold voltage distribution is not lower than the writing verifying voltage, it is decided that the writing operation is completed. If the number of memory cells with incomplete writing is not larger than a predetermined value, “artificial pass scheme” may be used to artificially complete a writing operation.

However, even if the lower limit value of the threshold voltage distribution is not lower than the writing verifying voltage immediately after a writing operation, trapped charge may be drawn from the memory cells several seconds or several minutes after a verifying operation. Moreover, the lower limit value of the threshold voltage distribution may be changed to a lower value than the writing verifying voltage.

Such a phenomenon has occurred more frequently as memory cells have decreased in size. The lower limit value of the threshold voltage distribution is reduced because charge trapped by the floating gate is drawn or charge trapped by, for example, the gate insulating film or a gate-side septum is drawn with the passage of time. Such a reduction in the lower limit value of the threshold voltage distribution may cause erroneous reading in a reading operation.

Thus, in the present embodiment, a positive voltage is applied to a substrate side after the completion of a program, which will be described later. This draws electrons trapped by, for example, the gate oxide film (tunnel oxide film) or an insulating film on the side wall of the floating gate and suppresses a reduction in threshold voltage after verification, optimizing a threshold voltage distribution width. Thus, erroneous reading can be prevented in a reading operation.

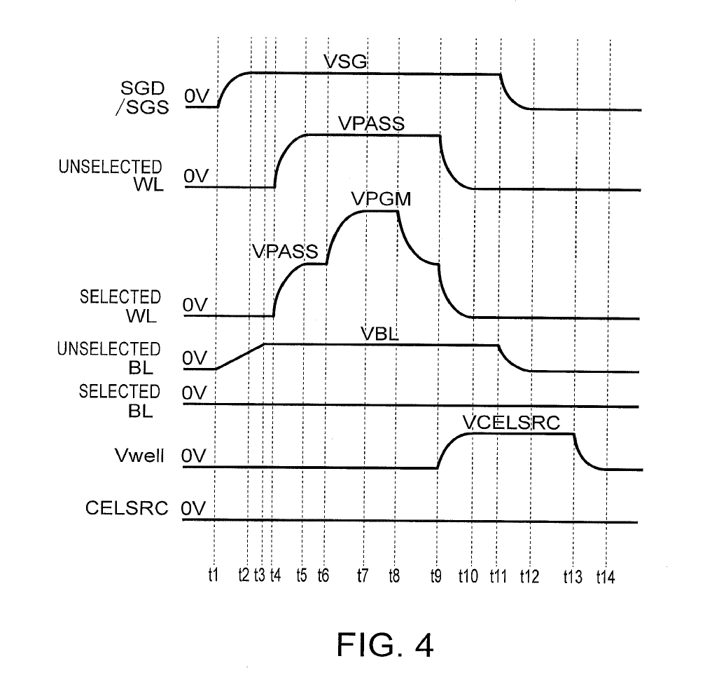

FIG. 4 is a timing chart showing an example of operating wavelengths in a writing operation and an operation for suppressing electron trap of the NAND flash memory 100 shown in FIG. 1. The bit line BL selected for writing is denoted as, for example, the bit line BL1 in FIG. 1 and is denoted as “selected BL” in FIG. 4. The bit line BL unselected for writing is denoted as, for example, the bit lines BL0 and BL2 to BLn in FIG. 1 and is denoted as the unselected BL in FIG. 4. Moreover, the selected word line WL is denoted as the selected WL in FIG. 4. The unselected word line WL that is not selected is denoted as the unselected WL in FIG. 4. Moreover, the memory cells M unselected for writing are denoted as, here, for example, the memory cells M0 and 2 to 31 in FIG. 1. The selected memory cells M for writing are denoted as, here, for example, the memory cell M1 in FIG. 1.

As shown in FIG. 4, the voltage of each part is set at 0 V in an initial state (at and before time t1).

At time t1 to time t2, the control circuit 10 increases the voltages of the two select gate lines SGD and SGS from 0 V to a voltage VSG. This turns on the selecting gate transistors SG0 and SG1.

At time t1 to time t3, the control circuit 10 increases the unselected bit line BL from 0 V to a voltage VBL to unselect the bit lines BL to be unselected, other than the selected bit lines BL for writing.

The bit line BL having a large wiring capacity requires a long charging time and thus increases in voltage after the voltage rising of the two select gate lines SGD and SGS (time t1 to time t3).

After that, at time t4 to time t5, the control circuit 10 raises the voltages of the selected word line WL and the unselected word line WL from 0 V to a writing pass voltage VPASS.

Specifically, when data is written in the selected memory cell M, the voltage of the word line WL connected to the control gate of the unselected memory cell M is set at the writing pass voltage VPASS.

This boosts the channel voltage of the memory cell M unselected for writing, preventing writing in the unselected memory cell M.

Furthermore, at time t6 and time t7, the control circuit 10 applies the writing voltage VPGM, which is higher than the writing pass voltage VPASS, to the selected word line WL connected to the selected memory cell M for writing (in this case, for example, the memory cell M1 in FIG. 1). At this point, the voltages of the well SW and the source line CELSRC are set at 0 V.

Thus, a predetermined potential difference is applied to the selected memory cell M, electrons are injected into the floating gate FG of the selected memory cell M from the substrate (well SW), and then data is written in the selected memory cell M.

After the application of the writing voltage VPGM, at time t8 to time t9, the control circuit 10 reduces the voltage of the selected word line WL from the writing voltage VPGM to the writing pass voltage VPASS.

After that, at time t9 to time t10, the control circuit 10 reduces the voltage of the selected word line WL from the writing pass voltage VPASS to 0 V.

At time t9, the control circuit 10 reduces the voltage of the unselected word line WL, which is connected to the control gate of the unselected memory cell M, from the writing pass voltage VPASS to 0 V when the voltage of the selected word line WL connected to the control gate of the selected memory cell M decreases from the writing pass voltage VPASS.

In this way, the selected word line WL is reduced to 0 V simultaneously after the unselected word line WL is temporarily reduced to the writing pass voltage VPASS to be synchronized. In this way, the voltage of the selected word line WL is not rapidly reduced from the writing voltage VPGM to 0 V. This suppresses an overshoot of the voltage of the selected word line WL so as to reduce damage to a peripheral transistor (not shown) that receives a voltage transferred from the word line.

At time t9 to time t13, the control circuit 10 increases the voltage of the substrate (well SW) from 0 V to a low positive voltage. The positive voltage is a low voltage of about 3 to 4 V. Specifically, after data is written in the selected memory cell M, the voltage of the selected word line WL is set at 0 V. In this state, the substrate (well SW) is controlled to a positive voltage (Specifically, the voltage of the substrate is controlled to be higher than the voltage of the selected word line WL connected to the selected memory cell M).

Specifically, the control circuit 10 sets the voltage of the selected word line WL connected to the control gate of the selected memory cell M, at the writing voltage VPGM. After data is written in the selected memory cell M, the control circuit 10 reduces the voltage of the selected word line WL, which is connected to the control gate of the selected memory cell M, from the writing voltage VPGM to the writing pass voltage VPASS. Subsequently, when the selected word line WL is reduced from the writing pass voltage VPASS to 0 V, the control circuit 10 controls the voltage of the substrate (well SW) to a voltage higher than that of the selected word line WL connected to the selected memory cell M.

Thus, at time t10 to time t13, when the voltages of the selected word line WL and the unselected word line WL decrease to 0 V, there arises a state that a weak erasure stress (a voltage with reversed polarity from writing) is applied to the memory cell.

As described above, data is written in the selected memory cell of the memory cells M, and then the voltage of the substrate (well) is controlled for a specified period (time t10 to time t13) to be higher than the voltage of the word line connected to the selected memory cell.

Electrons trapped at an electron easily drawing level by at least a tunnel insulating film (including the above side wall) are drawn by the erasure stress to the substrate (well SW), removing electrons at an unstable level during verification. This can actually suppress a reduction in threshold value when a threshold value is read after writing.

Subsequently, at time t12, the control circuit 10 reduces the voltages of the unselected bit line BL and the select gate lines SGD and SGS to 0 V, and then at time t13, the control circuit 10 reduces the voltage Vwell of the well SW (Specifically, the erasure stress is applied to the memory cell M until time t13).

After the specified period (time t10 to time t13), the control circuit 10 performs a verifying operation on the memory cell M for writing. If the threshold voltage of the memory cell M does not reach a desired value, a writing operation is performed again in the same sequence.

The time for applying the voltages and the erasure stress (time t10 to time t13) can be properly tuned so as to optimize detrapping of electrons.

The nonvolatile semiconductor memory according to the present embodiment can suppress a reduction in threshold voltage. This can suppress deterioration of data retention in the memory cells.

### Second Embodiment

In the present embodiment, another operation example of a nonvolatile semiconductor memory will be described below. The nonvolatile semiconductor memory of the present embodiment is identical in configuration to the first embodiment.

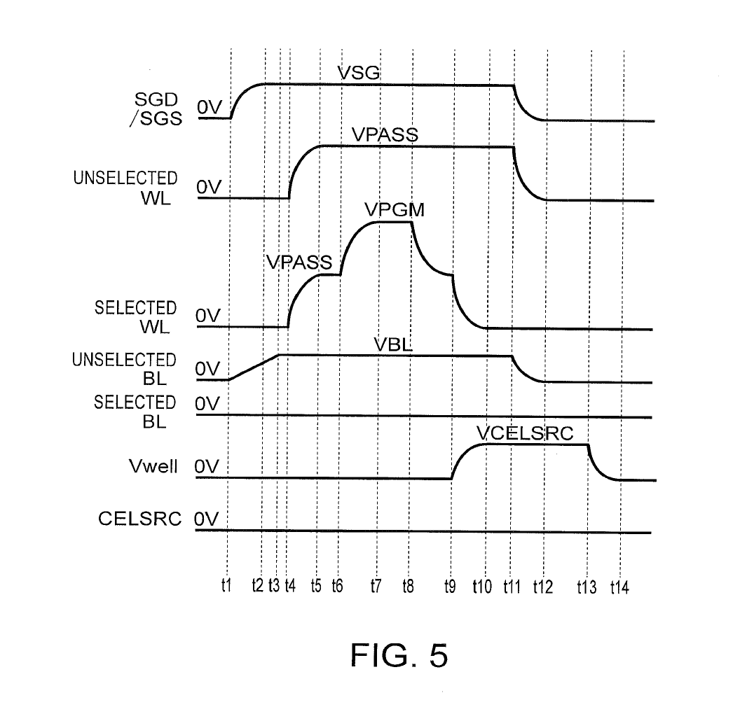

FIG. 5 is a timing chart showing another example of operating wavelengths in a writing operation and an operation for suppressing electron trap in the NAND flash memory 100 of FIG. 1.

As shown in FIG. 5, the present embodiment is different from the first embodiment in timing to reduce the voltage of an unselected word line WL. In the first embodiment, at time t9 to time t10, the control circuit 10 reduces the voltage of the unselected word line WL. In the present embodiment, however, a control circuit 10 keeps the voltage of a unselected word line WL until time t11 and then reduces the voltage of an unselected word line WL from a writing pass voltage VPASS to 0 V.

Specifically, in a specified period (time t10 to time t13) of the present embodiment, the control circuit 10 reduces the voltage of the unselected word line WL, which is connected to the control gate of an unselected memory cell M, from the writing pass voltage VPASS to 0 V.

In the above first embodiment, a voltage difference appears across the substrate (well SW) and the floating gate FG. In contrast to this, in the present embodiment, as described above, an electric field is applied in a lateral direction (the neighboring direction of the memory cells M), accelerating detrapping of electrons having been trapped in an insulating film or the like on the side wall of the memory cell M.

In the specified period (time t10 to time t13), the voltage of the unselected word line WL connected to the unselected memory cell M is reduced from the writing pass voltage VPASS to 0 V. Thus, erroneous erasure caused by a weak erasure stress applied to the selected memory cell M for writing is expected to decrease.

Other operations and function of the nonvolatile semiconductor memory according to the present embodiment are similar to those of the first embodiment.

The nonvolatile semiconductor memory according to the present embodiment can suppress a reduction in threshold voltage. This can suppress deterioration of data retention in the memory cells.

### Third Embodiment

In the present embodiment, still another operation example of a nonvolatile semiconductor memory will be described below. The nonvolatile semiconductor memory of the present embodiment is identical in configuration to the first embodiment.

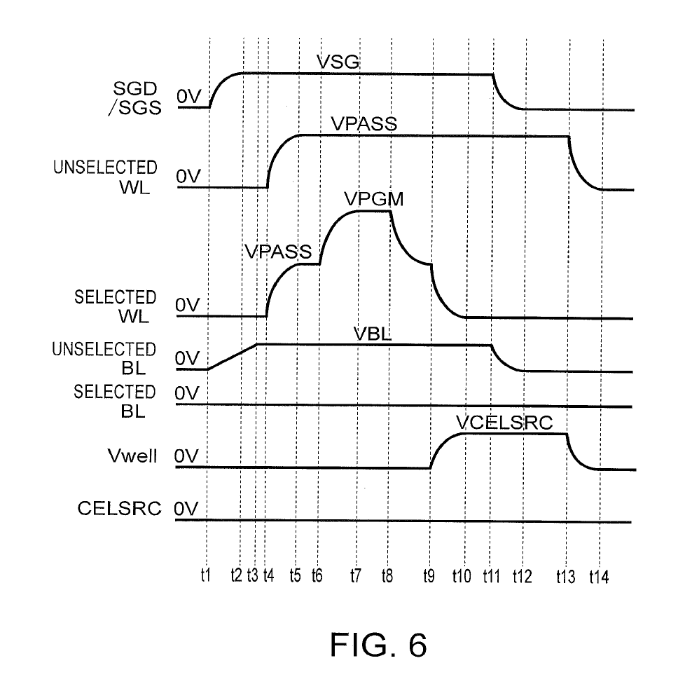

FIG. 6 is a timing chart showing still another example of operating wavelengths in a writing operation and an operation for suppressing electron trap in the NAND flash memory 100 of FIG. 1.

As shown in FIG. 6, the present embodiment is different from the first and second embodiments in timing to reduce the voltage of an unselected word line WL.

Specifically, after a specified period (time t10 to time t13), the control circuit 10 reduces the voltage of an unselected word line WL connected to the control gate of an unselected memory cell from a writing pass voltage VPASS to 0 V.

In this way, in the above first embodiment, the voltage of the unselected word line WL is reduced at time t9 to t10, whereas in the present embodiment, the timing to reduce the voltage of the unselected word line WI is delayed to time t13. This can suppress erroneous erasure while accelerating detrapping of electrons having been trapped in an insulating film or the like on the side wall of a memory cell M.

Other operations and function of the nonvolatile semiconductor memory according to the present embodiment are similar to those of the first embodiment. The nonvolatile semiconductor memory according to the present embodiment can suppress a reduction in threshold voltage. This can suppress deterioration of data retention in the memory cells.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory comprising:
a memory cell array, the memory cell array including a memory string and a matrix of a plurality of memory cell units, the memory string containing a plurality of memory cells that are provided on the substrate, store data according to a threshold voltage, allow electrical writing and erasure of data, and are connected in series, the memory cell unit containing a first selecting gate transistor that connects a first end of the memory string to a bit line and a second selecting gate transistor that connects a second end of the memory string to a source line; and
a driver that controls a voltage of a substrate,
wherein after data is written in selected one of the memory cells, the voltage of the substrate is controlled for a specified period to be higher than a voltage of a word line connected to the selected memory cell.

2. The nonvolatile semiconductor memory according to claim 1, wherein after the voltage of the word line connected to a control gate of the selected memory cell is set at a writing voltage and data is written in the selected memory cell, the voltage of the word line connected to the control gate of the selected memory cell is reduced from the writing voltage to a writing pass voltage, and then the voltage of the substrate is controlled to be higher than the voltage of the word line connected to the selected memory cell when the voltage of the word line is reduced from the writing pass voltage.

3. The nonvolatile semiconductor memory according to claim 2, wherein when data is written in the selected memory cell, a voltage of a word line connected to a control gate of unselected one of the memory cells is set at the writing pass voltage.

4. The nonvolatile semiconductor memory according to claim 3, wherein when the voltage of the word line connected to the control gate of the selected memory cell is reduced from the writing pass voltage, the voltage of the word line connected to the control gate of the unselected memory cell is reduced from the writing pass voltage.

5. The nonvolatile semiconductor memory according to claim 3, wherein the voltage of the word line connected to the control gate of the unselected memory cell is reduced from the writing pass voltage in the specified period.

6. The nonvolatile semiconductor memory according to claim 3, wherein the voltage of the word line connected to the control gate of the unselected memory cell is reduced from the writing pass voltage after the specified period.

7. The nonvolatile semiconductor memory according to claim 1, wherein a verifying operation is performed after the specified period.

8. The nonvolatile semiconductor memory according to claim 1, wherein the memory cell includes:
a tunnel insulating film provided on the substrate;
a charge storage layer provided on the tunnel insulating film;
an intermediate insulating film provided on the charge storage layer; and
a control gate provided on the second insulating film.

9. The nonvolatile semiconductor memory according to claim 1, wherein after data is written in the selected memory cell, the voltage of the substrate is controlled to a positive voltage while the voltage of the selected word line is set at 0 V.

10. The nonvolatile semiconductor memory according to claim 1, wherein after data is written in the selected memory cell, the voltage of the substrate is controlled to be higher than the voltage of the word line connected to the selected memory cell, allowing removal of electrons trapped at least in the tunnel insulating film.

11. The nonvolatile semiconductor memory according to claim 1, wherein the nonvolatile semiconductor memory is an NAND flash memory.

12. A method of controlling a nonvolatile semiconductor memory,
the nonvolatile semiconductor memory comprising a memory cell array including a memory string and a matrix of a plurality of memory cell units, the memory string containing a plurality of memory cells that are provided on the substrate, store data according to a threshold voltage, allow electrical writing and erasure of data, and are connected in series, the memory cell unit containing a first selecting gate transistor that connects a first end of the memory string to a bit line and a second selecting gate transistor that connects a second end of the memory string to a source line,
the method comprising controlling, after data is written in selected one of the memory cells, the voltage of the substrate for a specified period to be higher than a voltage of a word line connected to the selected memory cell.

13. The method of controlling the nonvolatile semiconductor memory according to claim 12, wherein after the voltage of the word line connected to a control gate of the selected memory cell is set at a writing voltage and data is written in the selected memory cell, the voltage of the word line connected to the control gate of the selected memory cell is reduced from the writing voltage to a writing pass voltage, and then the voltage of the substrate is controlled to be higher than the voltage of the word line connected to the selected memory cell when the voltage of the word line is reduced from the writing pass voltage.

14. The method of controlling the nonvolatile semiconductor memory according to claim 13, wherein when data is written in the selected memory cell, a voltage of a word line connected to a control gate of unselected one of the memory cells is set at the writing pass voltage.

15. The method of controlling the nonvolatile semiconductor memory according to claim 14, wherein when the voltage of the word line connected to the control gate of the selected memory cell is reduced from the writing pass voltage, the voltage of the word line connected to the control gate of the unselected memory cell is reduced from the writing pass voltage.

16. The method of controlling the nonvolatile semiconductor memory according to claim 15, wherein the voltage of the word line connected to the control gate of the unselected memory cell is reduced from the writing pass voltage in the specified period.

17. The method of controlling the nonvolatile semiconductor memory according to claim 15, wherein the voltage of the word line connected to the control gate of the unselected memory cell is reduced from the writing pass voltage after the specified period.

18. The method of controlling the nonvolatile semiconductor memory according to claim 12, wherein a verifying operation is performed after the specified period.

19. The method of controlling the nonvolatile semiconductor memory according to claim 12, wherein after data is written in the selected memory cell, the voltage of the substrate is controlled to a positive voltage while the voltage of the selected word line is set at 0 V.

20. The method of controlling the nonvolatile semiconductor memory according to claim 12, wherein after data is written in the selected memory cell, the voltage of the substrate is controlled to be higher than the voltage of the word line connected to the selected memory cell, allowing removal of electrons trapped at least in the tunnel insulating film.
